(19) United States
(12) Patent Application Publication
(10) Pub. No.: US 2026/0286508 A1
(43) Pub. Date: Sep. 24, 2026

(54) METHOD FOR PRODUCING A SILICON CARBIDE SUBSTRATE

(71) Applicant: Soitec, BERNIN (FR)

(72) Inventors: Hugo Biard, BERNIN (FR); Sidoine Odoul, BERNIN (FR); Christophe Maleville, BERNIN (FR)

(21) Appl. No.: 19/168,193

(22) PCT Filed: Mar. 28, 2024
(86) PCT No.: PCT/EP2024/058444

§ 371 Date: Sep. 23, 2025

(30) Foreign Application Priority Data
Mar. 29, 2023 (FR) FR2302989

(51) Int. Cl. C23C 16/01; B32B 18/00; B32B 37/00; B32B 37/24; B32B 38/00; B32B 38/10; C23C 16/32; C23C 16/56

(52) U.S. Cl. CPC C23C 16/01; B32B 18/00; B32B 37/025; B32B 38/0008; B32B 38/0012; B32B 38/0036; B32B 38/10; C23C 16/325; C23C 16/56; B32B 2037/243; B32B 2037/246; B32B 2038/0016; B32B 2038/0048; B32B 2307/704; B32B 2307/7376; B32B 2309/02; B32B 2309/105; B32B 2310/0418; B32B 2310/14; B32B 2313/04; B32B 2315/02; B32B 2457/14

(57) ABSTRACT

A method for producing a substrate comprising a polycrystalline silicon carbide layer and a monocrystalline silicon carbide layer in direct contact with the polycrystalline silicon carbide layer, the method successively comprising the following steps of: —transferring a first monocrystalline silicon carbide layer onto a front face of a graphite temporary support substrate, —depositing polycrystalline silicon carbide on the first monocrystalline silicon carbide layer to form the polycrystalline silicon carbide layer, and —removing the graphite temporary support substrate.

### CROSS-REFERENCE TO RELATED APPLICATIONS

This application is a national phase entry under 35 U.S.C. § 371 of International Patent Application PCT/EP2024/058444, filed Mar. 28, 2024, designating the United States of America and published as International Patent Publication WO 2024/200627 A1 on Oct. 3, 2024, which claims the benefit under Article 8 of the Patent Cooperation Treaty of French Patent Application Serial No. FR2302989, filed Mar. 29, 2023.

### TECHNICAL FIELD

The present disclosure relates generally to the field of silicon carbide substrates for the formation of electronic components. More particularly, the present disclosure proposes a process for manufacturing a substrate comprising a layer of polycrystalline silicon carbide and a layer of single-crystal silicon carbide.

### BACKGROUND

Single-crystal silicon carbide (sc-SiC) is used in the formation of electronic components, for example, for applications in radio frequency or power electronics.

The preparation of sc-SiC is complex and costly. For this reason, instead of using a bulk sc-SiC substrate, a polycrystalline silicon carbide (p-SiC) substrate is commonly used, with a layer of sc-SiC on its surface in which the electronic components are formed. Such substrates are typically manufactured using a Smart Cut™ process, in which a layer of sc-SiC is transferred onto a p-SiC support substrate from a donor substrate.

In order to ensure good mechanical and electrical contact between the support substrate and the sc-SiC layer, the support substrate must have a homogeneous crystal quality and a very smooth surface. Such a Smart Cut™ process therefore requires careful preparation of the p-SiC support substrate. This preparation involves the deposition of a thick layer of p-SiC onto a temporary substrate, followed by the removal of the temporary substrate. A significant thickness is then removed from the p-SiC layer in order to retain just a thin portion having a crystal quality suitable for the deposition of an sc-SiC layer. Thus, the thick p-SiC layer typically has an initial thickness of between 900 and 3000 μm. After removal of the portion of inferior crystal quality, a thickness of typically around 350 μm is retained, which has a crystal quality suitable for receiving an sc-SiC layer. This process thus involves a large consumption of p-SiC, which is removed before the deposition of the sc-SiC layer and is therefore not used in the substrate to be manufactured.

Preparation for the Smart Cut™ process also involves laborious steps to prepare the p-SiC surface in order to obtain a very smooth surface. Such a preparation is necessary for the deposition of the sc-SiC layer in order to obtain good mechanical and electrical contact at the interface between the p-SiC support substrate and the sc-SiC layer. These preparation steps typically comprise treatments such as mechanical and chemical polishing. However, these treatments are difficult to perform on silicon carbide and require a considerable amount of time due to its high hardness. The grain boundaries present in the polycrystalline material make surface smoothing even more difficult. Also, mechanical treatment involves a risk of breakage, rendering the substrate unusable.

### BRIEF SUMMARY

One objective of the present disclosure is to design a process for manufacturing a substrate comprising a layer of polycrystalline silicon carbide and a layer of single-crystal silicon carbide, which process makes it possible to dispense with the steps of preparing a polycrystalline silicon carbide support substrate described above.

To this end, the present disclosure proposes a process for manufacturing a substrate comprising a layer of polycrystalline silicon carbide and a layer of single-crystal silicon carbide in direct contact with the layer of polycrystalline silicon carbide, the process involving the following successive steps:
transferring a first layer of single-crystal silicon carbide onto a front face of a graphite temporary support substrate,
depositing polycrystalline silicon carbide onto the first layer of single-crystal silicon carbide to form the polycrystalline silicon carbide layer,
removing the graphite temporary support substrate.

Such a graphite temporary support substrate is particularly suitable because its thermal expansion coefficient is close to that of single-crystal silicon carbide. Thus, the mechanical stresses that occur during cooling after the deposition steps are minimized. The use of such a temporary support substrate thus prevents the substrate from breaking during this step.

In the present text, the term “successively” means that the steps are performed in the order in which they are indicated, without excluding the implementation of one or more intermediate steps. Such intermediate steps may, for example, relate to the preparation of the surface of the transferred single-crystal SiC layer prior to the deposition of the polycrystalline SiC layer.

Advantageously, the process also comprises, prior to the deposition of polycrystalline silicon carbide, the transfer of a second layer of single-crystal silicon carbide onto a rear face of the temporary support substrate, the deposition of polycrystalline silicon carbide comprising the formation of a second layer of polycrystalline silicon carbide on the second layer of single-crystal silicon carbide.

The use of the temporary support substrate on both of its free faces allows the process yield to be increased.

The process may comprise the application of a bonding layer between each layer of single-crystal silicon carbide and the temporary support substrate.

Preferably, the transfer of each layer of single-crystal silicon carbide onto the temporary support substrate involves the following steps:
forming an embrittlement zone by implanting atomic species into a single-crystal silicon carbide donor substrate,
bonding the donor substrate to a free face of the temporary support substrate,
detaching the donor substrate along the embrittlement zone so as to transfer a layer of single-crystal silicon carbide onto the temporary support substrate.

Advantageously, each layer of polycrystalline silicon carbide is deposited by chemical vapor deposition. Chemical vapor deposition ensures very good electrical and mechanical contact between the p-SiC layer and the sc-SiC layer.

Advantageously, the process also comprises heat treatment after deposition of a polycrystalline silicon carbide layer at a temperature above the deposition temperature. Preferably, the heat treatment is performed at a temperature greater than or equal to 1700° C.

The removal of the temporary support substrate may involve combustion of the graphite under a stream of oxygen at a temperature between 800° C. and 900° C. In certain embodiments, the removal of the temporary support substrate comprises chemical etching or oxygen plasma etching. The removal of the temporary support substrate may comprise a grinding step.

Advantageously, the thickness of the temporary support substrate is between 1 and 15 mm. The thickness of the first layer of single-crystal silicon carbide may be between 400 nm and 5 μm, preferably between 400 nm and 2 μm, and more preferably between 400 nm and 1 μm. Advantageously, the thickness of the first layer of polycrystalline silicon carbide is between 100 μm and 2 mm.

In certain embodiments, the front face of the graphite temporary support has a first size, and the first layer of single-crystal silicon carbide has a second size less than or equal to half the first size, such that the first layer forms a first block, the process also comprising the transfer of at least a second single-crystal silicon carbide block onto the front face of the temporary support substrate so that the first and second blocks are arranged side by side on the front face of the temporary support substrate, the deposition of the polycrystalline silicon carbide layer comprising the formation of a respective layer of polycrystalline silicon carbide on each block.

The present disclosure also relates to an intermediate substrate comprising:
a graphite temporary support substrate,
a first layer of single-crystal silicon carbide arranged on a front face of the temporary support substrate, and
a first layer of polycrystalline silicon carbide arranged in direct contact with the first layer of single-crystal silicon carbide.

Advantageously, the single-crystal silicon carbide layer has a thickness of between 400 nm and 5 μm, preferably between 400 nm and 2 μm, and more preferably between 400 nm and 1 μm, and the polycrystalline silicon carbide layer has a thickness of between 100 μm and 2 mm.

Preferably, the front face of the graphite temporary support substrate has a first size, and the first layer of single-crystal silicon carbide has a second size less than or equal to half the first size, so that the first layer forms a first block, the intermediate substrate also comprising at least a second single-crystal silicon carbide block, such that the first and second blocks are arranged side by side on the front face of the temporary support substrate, a polycrystalline silicon carbide layer being arranged on each single-crystal silicon carbide block.

### BRIEF DESCRIPTION OF THE DRAWINGS

Other features and advantages of the present disclosure will become apparent from the detailed description that follows, with reference to the accompanying drawings.

FIG. 1 illustrates the formation of an embrittlement zone in an sc-SiC donor substrate.

FIG. 2 illustrates the transfer of an sc-SiC layer onto a temporary support substrate.

FIG. 3 is a schematic view of a temporary support substrate including an sc-SiC layer.

FIG. 4 is a schematic view of a temporary support substrate including an sc-SiC layer and a p-SiC layer.

FIG. 5 illustrates a substrate comprising a polycrystalline silicon carbide layer and a single-crystal silicon carbide layer.

FIG. 6 is a schematic view of a temporary support substrate including two sc-SiC layers.

FIG. 7 is a schematic view of a temporary support substrate including two sc-SiC layers and two p-SiC layers.

FIG. 8 illustrates two substrates obtained from the temporary support substrate of FIG. 7.

FIG. 9 illustrates a temporary support substrate including several juxtaposed layers of sc-SiC.

### DETAILED DESCRIPTION

In the process according to the present disclosure, a temporary support substrate is used onto which a first layer of single-crystal silicon carbide (sc-SiC) is transferred. The temporary support substrate acts as a mechanical support for the sc-SiC layer. Due to its temporary nature, the interface between the temporary support substrate and the sc-SiC layer requires only relatively simple basic preparation. This preparation does not involve any complex or critical steps in terms of cleaning, homogeneity, or adhesion of the layer to the substrate.

A layer of polycrystalline silicon carbide (p-SiC) is subsequently deposited onto this first layer of sc-SiC while the first layer is held on the temporary substrate. During deposition, the temporary support substrate ensures the mechanical stability of the sc-SiC layer. The temporary support substrate is subsequently removed.

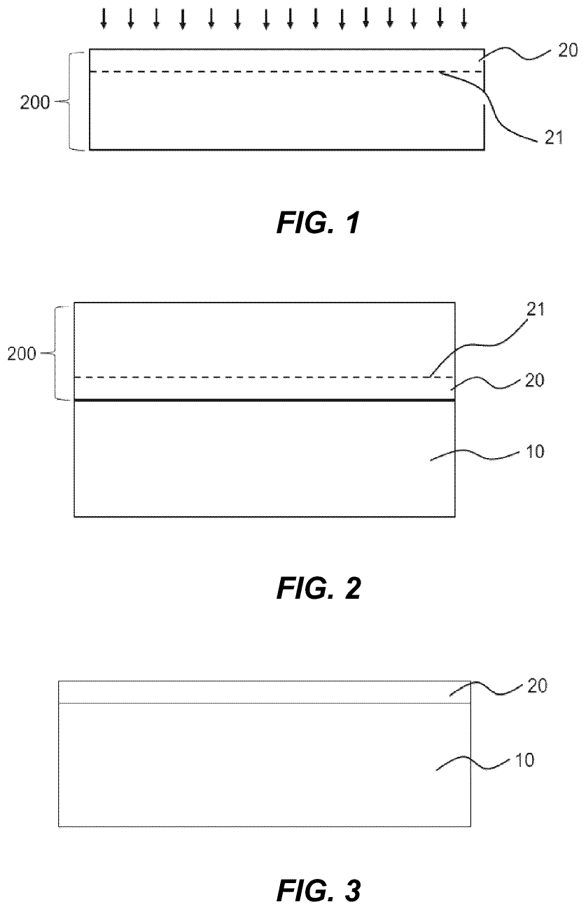

FIGS. 1 to 5 illustrate the steps of a process according to the present disclosure. With reference to FIG. 1, as shown schematically by the arrows, ionic species are implanted into an sc-SiC donor substrate 200. The ionic species are, for example, hydrogen and/or helium. An embrittlement zone 21 is thus created, defining a layer 20 of sc-SiC to be transferred.

With reference to FIG. 2, the donor substrate 200 thus implanted is bonded to a graphite temporary support substrate 10. Bonding may be performed by way of an adhesive layer that is applied to the donor substrate and/or to the temporary support substrate before the two substrates are placed in contact. The adhesive layer is, for example, a silicon layer, a tungsten layer, a polymer layer, or an oxide layer.

Typically, the graphite support substrate has the same surface area as the donor substrate 200, for example, a diameter of about 150 mm or 200 mm. This size facilitates the handling of the substrates bonded together and allows the use of equipment available in the manufacture of semiconductor substrates. Alternatively, the temporary support substrate may have surface dimensions larger than the dimensions of the donor substrate 200. A larger surface area of the temporary support substrate makes it possible to avoid edge effects and, notably, deformations (warping) near the edges of the substrate during the bonding step and the deposition steps described below. The thickness of the temporary support substrate is typically between 1 and 15 mm to ensure mechanical stability sufficient to maintain the sc-SiC layer during the process.

With reference to FIG. 3, the donor substrate 200 is detached along the embrittlement zone 21, for example, by heat treatment or by the application of a mechanical stress, which leads to the transfer of the sc-SiC layer 20 onto the graphite temporary support substrate 10. A finishing treatment for the transferred layer 20 can then be performed, for example, polishing and/or heat treatment. Such a treatment is used to heal defects related to implantation and to smooth the free surface of the sc-SiC layer 20 so as to optimize the surface quality for the following steps. In the present disclosure, a finishing treatment may often be avoided because the p-SiC layer will be deposited on the face resulting from the detachment. It is thus not necessary to provide for increased smoothing of the surface obtained during detachment, since no bonding is performed on this surface. Furthermore, any roughness will be compensated for during the deposition of the p-SiC layer.

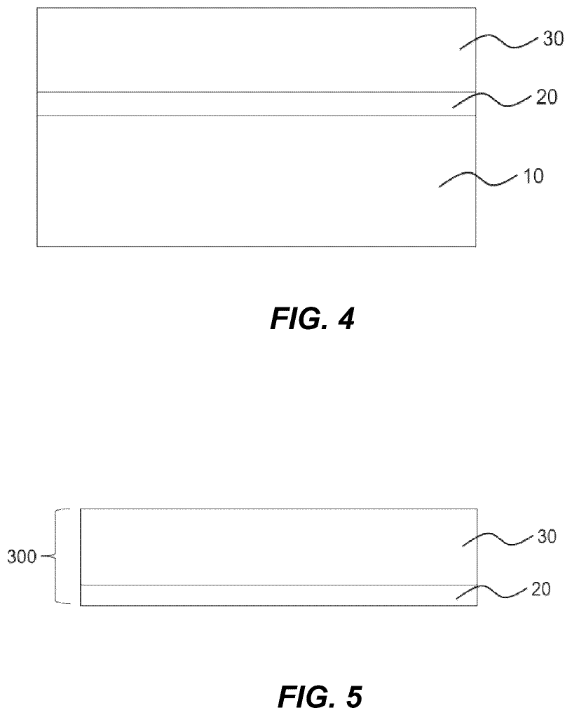

With reference to FIG. 4, a layer of polycrystalline silicon carbide 30 is subsequently deposited onto the free face of the sc-SiC layer 20 arranged on the temporary support substrate 10. Preferably, the p-SiC layer is deposited by a chemical vapor deposition (CVD) process. During CVD deposition, silicon and carbon atoms are sent to the sc-SiC layer 20. Thus, direct chemical bonds are established between the atoms of the sc-SiC layer 20 and the atoms of the p-SiC layer 30 during deposition, with crystallographic continuity at the interface between the two layers. Chemical vapor deposition thus allows very good electrical and mechanical contact between the p-SiC layer and the sc-SiC layer.

Typically, the deposition parameters are adjusted so that the p-SiC layer has a fine, micrometric microstructure. This allows the promotion of crystallographic continuity at the interface between the two layers, and thus limits mechanical deformation of the substrate being manufactured. By way of nonlimiting illustration, the p-SiC layer is deposited at a temperature of between 1100 and 1500° C.

CVD deposition is performed on the main surface of the sc-SiC layer 20. However, a certain amount of p-SiC may be deposited onto the edges of the substrate and will be removed in a subsequent step. Similarly, an amount of SiC may be deposited onto the rear face and removed with the temporary support substrate.

A heat treatment can then be applied so as to activate dopants in the sc-SiC layer 20 and the p-SiC layer 30. Heat treatment may also promote the relaxation of mechanical stresses in the substrate comprising the sc-SiC layer 20 and the p-SiC layer 30. These effects improve the crystal quality and thus the electrical and thermal conductivity at the interface between the sc-SiC layer and the p-SiC layer.

Such heat treatments are typically performed at a temperature of about 1700° C. By virtue of the bonding, the sc-SiC layer is held on the temporary support substrate 10 without risk of detachment during the heat treatment.

During the deposition of the p-SiC layer, for example, in a CVD chamber, material is often deposited onto the edges and/or the rear face of the substrate. If the edge of the temporary support substrate has been covered during the deposition of the p-SiC layer, removal of the edge of the substrate is performed to expose the edge of the sc-SiC layer and the temporary support substrate. Typically, the p-SiC deposited onto the edge of the substrate is removed by chemical etching, mechanical grinding or polishing, or heat treatment.

Alternatively, an indentation is created along the edge of the substrate using a diamond tip so as to form a mechanically embrittled zone. Mechanical action is subsequently applied to fracture the substrate along the embrittlement zone so as to remove the edge of the substrate.

With reference to FIG. 5, the temporary support substrate 10 is then removed. By way of nonlimiting illustration, the temporary support substrate 10 may be removed by combustion or chemical etching. For example, combustion may be performed under a stream of oxygen at a temperature of between 800 and 900° C. Chemical etching may, for example, be performed by the application of nitric acid or potassium hydroxide. Alternatively, the temporary support substrate may be removed by way of an oxygen plasma etching step. These steps also allow the removal of the bonding layer applied for the transfer of the sc-SiC layer.

In certain cases, a grinding step is also applied so as to remove the temporary support substrate without leaving any residue on the sc-SiC layer.

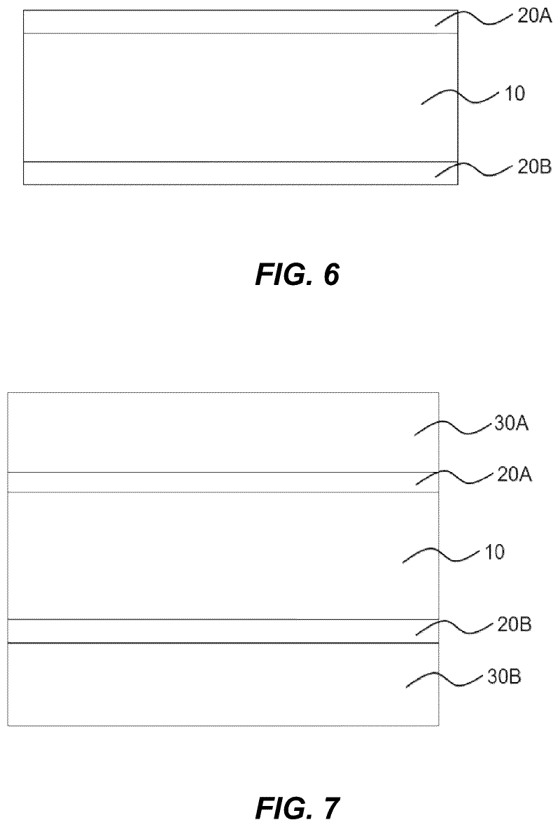

In certain embodiments, illustrated in FIGS. 6 to 8, both faces of the temporary support substrate are used to manufacture two substrates 300A and 300B, each comprising a thin layer of sc-SiC and a layer of p-SiC. With reference to FIG. 6, a first sc-SiC layer 20A is transferred to a front face of the graphite temporary support substrate 10, and a second sc-SiC layer 20B is transferred to a rear face of the same temporary support substrate 10. The two layers of sc-SiC may, for example, be deposited successively from the same sc-SiC donor substrate, or from two different sc-SiC substrates.

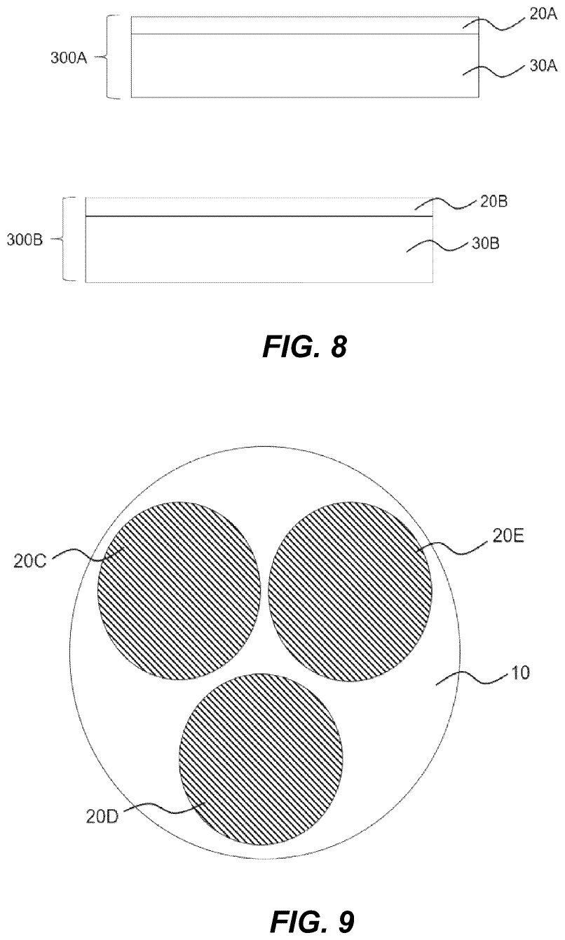

With reference to FIG. 7, a layer of p-SiC 30A, 30B is deposited onto each of the respective layers of sc-SiC 20A, 20B. Preferably, the two layers of p-SiC are deposited simultaneously in the same chamber, for example, a CVD chamber. This makes it possible to increase the efficiency of the process by performing the deposition of two layers instead of just one over a limited time, and in the same space of the CVD chamber. For such simultaneous deposition on both faces of the same substrate, a certain amount of p-SiC is typically deposited onto the edges of the substrate and will be removed in a subsequent step.

The other steps in a process using both faces of the temporary support substrate are performed in the same manner as described above for the process using only one face of the temporary support substrate.

In this embodiment, material is also deposited onto the edges of the support substrate and the respective p-SiC layers. For this reason, the edge of the substrate is removed so as to expose the edges of the two sc-SiC layers and of the temporary support substrate. Typically, the p-SiC deposited onto the edge of the substrate is removed by chemical etching, mechanical grinding or polishing, or heat treatment.

Alternatively, an indentation is created along the edge of the substrate using a diamond tip so as to form a mechanically embrittled zone. Mechanical action is subsequently applied to fracture the substrate along the embrittlement zone so as to remove the edge of the substrate.

This step affords access to the edge of the temporary support substrate for the step of removing the support substrate.

With reference to FIG. 8, after completion of layers 30A and 30B, their treatment on the temporary support substrate 10, and removal of the edge, the temporary support substrate 10 is removed, for example, by combustion or chemical etching. Two substrates 300A and 300B are obtained simultaneously. This variant makes it possible to increase the yield of the process by using the two opposite faces of the support substrate.

In certain embodiments, with reference to FIG. 9, a plurality of sc-SiC blocks 20C, 20D, 20E are transferred side by side onto a single face of a temporary support substrate 10. In this case, the temporary support substrate has a surface area that is significantly larger than that of the transferred sc-SiC blocks 20C, 20D, 20E. The blocks do not overlap, and typically an area between the edges of the respective blocks remains free on the temporary support substrate 10. The geometry of the blocks may be round, rectangular, or other. Depending on the shape and size of the blocks and of the temporary support substrate, an area near the edge of the temporary support substrate may also remain free.

It is also possible to transfer several respective sc-SiC blocks side by side on the front and rear faces of such a large temporary support substrate. This embodiment also allows the process yield to be optimized.

A layer of p-SiC is then simultaneously deposited over the entire surface of the temporary support substrate including the plurality of sc-SiC blocks 20C, 20D, 20E. The same steps and substrate treatments as described above for a single layer of p-SiC may be applied.

The deposited p-SiC layer is subsequently cut out in the free areas of the temporary support substrate that do not include any sc-SiC layer. By way of nonlimiting illustration, the areas of p-SiC deposited onto the free areas of the temporary support substrate are removed by laser cutting or cutting with a diamond tip. These methods enable efficient cutting of the p-SiC. The SiC deposited onto the edges of the graphite temporary support substrate is also removed so as to expose the edge of the support substrate for removal of the graphite. By way of nonlimiting illustration, the SiC on the front face of the temporary support substrate is first cut, and the SiC on the edges of the temporary support substrate is then removed. After this step, removal of the temporary support substrate is performed, for example, by combustion or chemical etching.

Several respective substrates are thus obtained from the several sc-SiC layers transferred at the beginning of the process.

Typically, after the production of one or more substrates comprising a thin layer of sc-SiC and a layer of p-SiC, final forming into shape is performed. Such a step may, for example, involve mechanical trimming and/or polishing to remove deposits on the edges of each substrate and to homogenize the edge of each substrate obtained.

Each layer of sc-SiC transferred to the temporary support substrate has a thickness of between 400 nm and 5 μm. Preferably, the thickness of the transferred sc-SiC layer is between 400 nm and 2 μm, and more preferably between 400 nm and 1 μm.

A layer of such a thickness is too thin to be self-supporting. During the deposition of each layer of p-SiC, the thin sc-SiC layer is held on the temporary support substrate by the bonding performed in the transfer step. The temporary support substrate ensures the mechanical integrity and stability of the sc-SiC layer during the deposition of the p-SiC layer. This allows a homogeneous p-SiC layer with good crystal quality to be deposited.

The use of a thin sc-SiC layer makes it possible to obtain a large number of substrates from the same sc-SiC donor substrate. The yield of such a donor substrate, which is difficult and laborious to produce, can thus be optimized. The limited thickness of the sc-SiC layer also allows a reduction in the impact of the slight difference in thermal expansion coefficient between the sc-SiC layer and the p-SiC layer, which may be present notably due to different doping of the two layers. The thickness also makes it possible to limit the deformation (warping) of the substrate to be produced, made up of the p-SiC layer 30 and the thin sc-SiC 20 layer. Moreover, the thinner the sc-SiC layer, the less energy is required to create the embrittlement zone for the transfer. It is therefore easier and more energy efficient to transfer thin sc-SiC layers.

Graphite has a thermal expansion coefficient close to that of single-crystal and polycrystalline silicon carbide. For this reason, it is particularly suitable as a temporary support substrate material for the manufacture of a substrate involving high-temperature steps. High-temperature steps include, for example, detachment of the donor substrate during the transfer of the sc-SiC layer, deposition of the p-SiC layer, such as vapor phase deposition, and any recrystallization and relaxation heat treatments and subsequent treatments. Moreover, graphite can be readily removed, for example, by grinding, chemical etching, and/or combustion. It is consequently not necessary to optimize the surface quality and bonding of the sc-SiC layer to facilitate removal of the temporary support substrate at the end of the process.

The temporary support substrate must be smooth enough to hold the sc-SiC layer during the deposition of the p-SiC layer without significant surface deformation. However, the process does not impose any constraints on the structure and quality of the graphite used, due to the temporary support substrate being removed for the finalization of the silicon carbide substrate.

Maintenance on the temporary support substrate by bonding prevents the risk of the support substrate detaching during high-temperature steps. A person skilled in the art will know how to choose the type of bonding as a function of the temperatures and environments expected in the process. Since the bonding is only temporary, the constraints relating thereto are relatively mild. The sole purpose of the bonding is to ensure the mechanical integrity of the sc-SiC layer during the deposition of the p-SiC layer. It is therefore not necessary to optimize the electrical or thermal conductivity through the bonding interface.

The p-SiC layer may thus be deposited at a temperature chosen as a function of the desired properties of the p-SiC layer. It is not necessary to limit the temperature window or other process parameters to prevent the sc-SiC layer from detaching from its support. Heat treatments, for example, for dopant activation and mechanical stress relaxation, may also be performed without any particular constraints imposed by the temporary support substrate.

Each p-SiC layer has a thickness of between 100 μm and 2 mm. Such a thickness is sufficient to make the substrate self-supporting over its entire area after removal of the temporary support substrate.

Due to the fact that the p-SiC layer is deposited directly onto a thin sc-SiC layer with good crystal quality, it allows high-quality p-SiC deposition over the entire thickness of the layer. This avoids the need for an additional step to remove a portion of the p-SiC. Following the deposition of p-SiC onto a surface of sc-SiC with good crystal quality, the interface between the respective p-SiC and sc-SiC layers has good mechanical, electrical and thermal coupling.

1. A method of manufacturing a substrate comprising a layer of polycrystalline silicon carbide and a layer of single-crystal silicon carbide in direct contact with the layer of polycrystalline silicon carbide, the method comprising the following successive steps:
transferring a first layer of single-crystal silicon carbide onto a front face of a graphite temporary support substrate;
depositing polycrystalline silicon carbide onto the first layer of single-crystal silicon carbide to form the polycrystalline silicon carbide layer; and
removing the graphite temporary support substrate.

2. The method of claim 1, further comprising, prior to the depositing polycrystalline silicon carbide, transferring a second layer of single-crystal silicon carbide onto a rear face of the temporary support substrate, the depositing polycrystalline silicon carbide comprising forming a second layer of polycrystalline silicon carbide on the second layer of single-crystal silicon carbide.

3. The method of claim 1, further comprising providing a bonding layer between each layer of single-crystal silicon carbide and the temporary support substrate.

4. The method of claim 1, wherein the transferring the first layer of single-crystal silicon carbide onto the temporary support substrate involves the following steps:
forming an embrittlement zone by implanting atomic species into a single-crystal silicon carbide donor substrate;
bonding the donor substrate to a free face of the temporary support substrate; and
detaching the donor substrate along the embrittlement zone so as to transfer a layer of single-crystal silicon carbide onto the temporary support substrate.

5. The method of claim 1, wherein the depositing polycrystalline silicon carbide is performed by chemical vapor deposition.

6. The method of claim 1, further comprising performing a heat treatment after the depositing polycrystalline silicon carbide, the heat treatment being performed at a temperature above a temperature at which the depositing polycrystalline silicon carbide is performed.

7. The method of claim 6, wherein the heat treatment is performed at a temperature greater than or equal to 1700° C.

8. The method of claim 1, wherein the removing the graphite temporary support substrate involves combustion of the graphite under a stream of oxygen at a temperature of between 800° C. and 900° C.

9. The method of claim 1, wherein the removing the graphite temporary support substrate involves chemical etching or oxygen plasma etching.

10. The method of claim 1, wherein the removing the graphite temporary support substrate involves a grinding step.

11. The method of claim 1, wherein a thickness of the graphite temporary support substrate is between 1 and 15 mm.

12. The method of claim 1, wherein a thickness of the first layer of single-crystal silicon carbide is between 400 nm and 5 μm.

13. The method of claim 1, wherein a thickness of the layer of polycrystalline silicon carbide is between 100 μm and 2 mm.

14. The method of claim 1, wherein the front face of the graphite temporary support substrate has a first size, and the first layer of single-crystal silicon carbide has a second size less than or equal to half the first size, such that the first layer of single-crystal silicon carbide forms a first block, the method further comprising transferring at least a second single-crystal silicon carbide block onto the front face of the graphite temporary support substrate to form a second block, the first block and the second block being arranged side by side on the front face of the graphite temporary support substrate, wherein the depositing polycrystalline silicon carbide comprises forming a respective layer of polycrystalline silicon carbide on each of the first block and the second block.

15. An intermediate substrate, comprising:
a graphite temporary support substrate;
a first layer of single-crystal silicon carbide on a front face of the graphite temporary support substrate; and
a first layer of polycrystalline silicon carbide in direct contact with the first layer of single-crystal silicon carbide.

16. The intermediate substrate of claim 15, wherein the first layer of single-crystal silicon carbide layer has a thickness of between 400 nm and 5 μm.

17. The intermediate substrate of claim 15, wherein the front face of the graphite temporary support substrate has a first size, and the first layer of single-crystal silicon carbide has a second size less than or equal to half the first size, the first layer of single-crystal silicon carbide forming a first block, the intermediate substrate further comprising at least a second layer of single-crystal silicon carbide forming a second block, the first block and the second block being arranged side by side on the front face of the graphite temporary support substrate, a polycrystalline silicon carbide layer disposed on each of the first block and the second block.

18. The method of claim 12, wherein the thickness of the first layer of single-crystal silicon carbide is between 400 nm and 2 μm.

19. The method of claim 18, wherein the thickness of the first layer of single-crystal silicon carbide is between 400 nm and 1 μm.
